(19) United States
(12) Patent Application Publication
(10) Pub. No.: US 2026/0013153 A1
(43) Pub. Date: Jan. 8, 2026

(54) ENHANCED BACK VIA LANDING METAL LAYER ADHESION

(71) Applicant: MACOM Technology Solutions Holdings, Inc., Lowell, MA (US)

(72) Inventors: Debdas Pal, Acton, MA (US); Kimberly Gehlert, Sterling, MA (US)

(21) Appl. No.: 18/762,335

(22) Filed: Jul. 2, 2024

(51) Int. Cl. H01L 21/768; H01L 23/48

(52) U.S. Cl. CPC H10D 1/694; H01L 21/76898; H01L 23/481

(57) ABSTRACT

Landing metal layers with improved adhesion to semiconductor substrates are described, along with semiconductor structures including the landing metal layers and components using the landing metal layers. An example semiconductor device includes a substrate with top and bottom surfaces, a landing metal layer over the top surface of the substrate, a via that extends through the substrate, and a bottom side metal layer. The bottom side metal layer extends over sidewalls of the via and electrically contacts an underside of the landing metal layer. For improved adhesion, the landing metal layer is diffused at least in part into the top surface of the substrate. The landing metal layer is diffused into the top surface of the substrate by an annealing or alloying process, and the techniques described herein help to avoid the delamination of the landing metal layer from the top surface of the substrate.

### BACKGROUND

A monolithic microwave integrated circuit (MMIC) is one example of a circuit structure that can be integrated on or over a single substrate. MMICs can incorporate passive electrical components or devices, such as capacitors, resistors, transmission lines, inductors, radio frequency (RF) couplers, and other passive components, along with active electrical components, such as transistors, diodes, and other active components. MMICs and related semiconductor structures can also incorporate vias formed through substrates for ground and other connections on the backsides of the substrates in some cases.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Landing metal layers with improved or enhanced adhesion to semiconductor substrates are described, along with semiconductor structures including the landing metal layers and circuit components that incorporate the landing metal layers. An example semiconductor device includes a substrate with top and bottom surfaces, a landing metal layer over the top surface of the substrate, a via that extends through the substrate, and a bottom side metal layer. The bottom side metal layer extends over sidewalls of the via and electrically contacts an underside of the landing metal layer. For improved adhesion, the landing metal layer includes a first or base metal layer on and diffused at least in part into the top surface of the substrate. The landing metal layer is diffused into the top surface of the substrate by an annealing or alloying process, and the techniques described herein help to avoid the delamination of the landing metal layer from the top surface of the substrate.

The landing metal layer includes a stack of metal layers in some examples. The stack of metal layers can include a platinum layer on and diffused at least in part into the top surface of the substrate and at least one of a titanium layer or a gold layer over the platinum layer. The stack of metal layers can also include the platinum layer on and diffused at least in part into the top surface of the substrate, a titanium layer, a second platinum layer, a gold layer, and a second titanium layer in other cases. In still other cases, the landing metal layer consists of a stack of the platinum layer on and diffused at least in part into a top surface of a substrate, a titanium layer over the platinum layer, a second platinum layer over the titanium layer, a gold layer over the second platinum layer, and a second titanium layer over the gold layer. In still other cases, the stack of metal layers includes a base metal layer of one of platinum, palladium, zinc, magnesium, titanium, nickel, tantalum, aluminum, or chromium on and diffused at least in part into the top surface of the substrate.

The semiconductor structure can also include an insulating layer over the landing metal layer and a second metal layer over the insulating layer in some examples. The landing metal layer, the insulating layer, and the second metal layer can form a metal-insulator-metal (MIM) capacitor. The second metal layer can be different in composition as compared to the landing metal layer. The second metal layer can include a titanium layer on the insulating layer. The second metal layer can consist of a stack of a titanium layer, a platinum layer over the titanium layer, a gold layer over the platinum layer, and a second titanium layer over the gold layer in one example.

The semiconductor structure and MIM capacitor can be part of a larger integrated structure including a number of active and passive devices. The second metal layer can be electrically coupled to a contact of an active semiconductor device by an interconnect metal layer. As one example, the second metal layer can be electrically coupled to a contact of an active semiconductor device by a metal air bridge. In other examples, the landing metal layer can be part of other circuit components, such as inductors, transmission lines, RF couplers, device interconnects, bond pads, and other components.

Another example semiconductor device includes a landing metal layer on and diffused at least in part into a top surface of a substrate, a via that extends through from a bottom surface to the top surface of the substrate under the landing metal layer, and a bottom side metal layer in the via and that electrically contacts an underside of the landing metal layer.

An example process for manufacturing a landing metal layer includes providing a substrate with a top surface and a bottom surface, depositing a landing metal layer over the top surface of the substrate, annealing the landing metal layer to diffuse the landing metal layer at least in part into the top surface of the substrate, etching a via opening through from the bottom surface to the top surface of the substrate, and depositing a bottom side metal layer over the bottom surface of the substrate, over sidewalls of the via, and that electrically contacts an underside of the landing metal layer. The process can also include, before the etching and after the annealing, forming an insulating layer over the landing metal layer, and depositing a second metal layer over the insulating layer.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments.

FIG. 1 depicts a partial sectional view of an example semiconductor structure with a metal layer and a through-substrate via.

FIG. 2 illustrates a detail area identified in FIG. 1.

FIG. 3 depicts a partial sectional view of an example semiconductor structure including a landing metal layer having improved adhesion and a through-substrate via according to various aspects of the embodiments.

FIG. 4 illustrates a detail area identified in FIG. 3 according to various aspects of the embodiments.

FIG. 5 illustrates an example process for forming a semiconductor structure with a landing metal layer having improved adhesion according to various aspects of the embodiments.

FIG. 6 illustrates another example process for forming a semiconductor structure with a landing metal layer having improved adhesion according to various aspects of the embodiments.

### DETAILED DESCRIPTION

Landing metal layers with improved or enhanced adhesion to semiconductor substrates are described, along with semiconductor structures including the landing metal layers and circuit components that incorporate the landing metal layers. An example semiconductor device includes a substrate with top and bottom surfaces, a landing metal layer over the top surface of the substrate, a via that extends through the substrate, and a bottom side metal layer. The bottom side metal layer extends over sidewalls of the via and electrically contacts an underside of the landing metal layer. For improved adhesion, the landing metal layer is diffused at least in part into the top surface of the substrate. The landing metal layer is diffused into the top surface of the substrate by an annealing or alloying process, and the techniques described herein help to avoid the delamination of the landing metal layer from the top surface of the substrate.

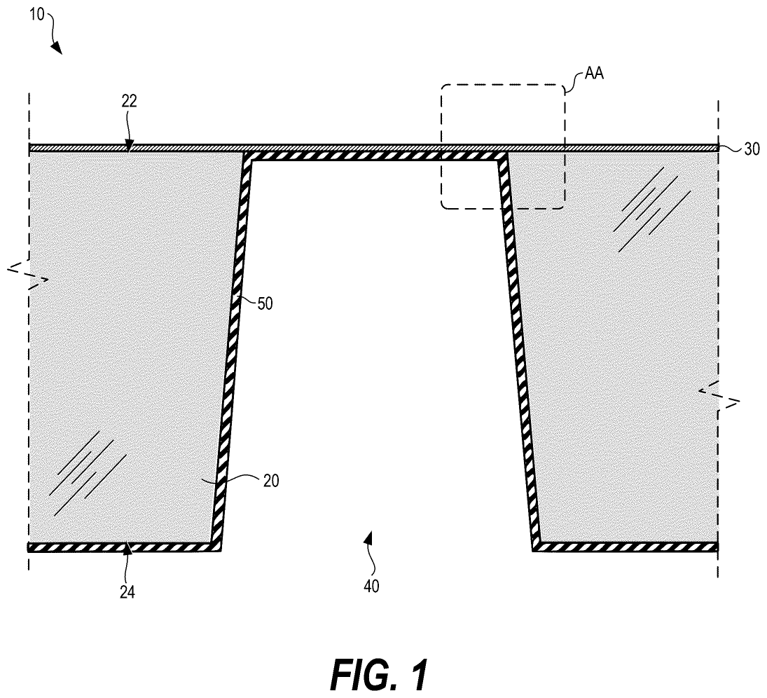

FIG. 1 depicts a partial sectional view of an example semiconductor structure 10. The semiconductor structure 10 is illustrated as a representative example. The semiconductor structure 10 and features of the semiconductor structure 10 are not drawn to any particular size or scale in FIG. 1. The thicknesses of the substrate, layers over the substate, and other features can vary as compared to that shown and as compared to each other. Example thicknesses are described below, although the concepts are not limited to use with substrates or layers having any particular thickness. Additionally, example materials of the substate and the layers over the substate are described below. However, the concepts described herein can be extended to use with other types of materials.

The semiconductor structure 10 includes a substrate 20 having a top surface 22 and a bottom surface 24, a metal layer 30 over the substrate 20, a via opening 40 (also “via 40”) that extends through from the bottom surface 24 to the top surface 22 of the substrate 20, and a bottom side metal layer 50 (also “metal layer 50”). The bottom side metal layer 50 extends at least in part over the bottom surface 24 of the substrate 20, over sidewalls of the via 40, and electrically contacts an underside of the metal layer 30 in the example shown. The semiconductor structure 10 is depicted to focus on the electrical coupling between the metal layer 30 over the top surface 22 of the substrate 20 and the bottom side metal layer 50 over the bottom surface 24 of the substrate 20, withing the via 40. Although not illustrated, the semiconductor structure 10 can be part of a larger integrated structure including a number of active and passive devices as would be understood in the field.

Through-substrate vias, such as the via 40, can be used for a range of purposes in monolithic microwave integrated circuits (MMICs) and related integrated semiconductor structures. As examples, the via 40 can be used as a conductive pathway to ground for sources of one or more field effect transistors (FETs) and for electrical couplings to capacitors, resistors, inductors, and other circuit components. The via 40 can also be used for passing radio frequency (RF) signals to the bottom surface 24 of the substrate 20 and for other interconnect purposes. The via 40 and the electrical coupling between the metal layers 30 and 50 is formed through a number of semiconductor manufacturing process steps. The steps to form the via 40 and the metal layers 30 and 50 can be a subset among a larger sequence of process steps relied upon to form the semiconductor structure 10. Ideally, the via 40 and the electrical coupling between the metal layers 30 and 50 should be robust, capable of withstanding any stresses induced during any subsequent manufacturing process steps, and also capable of withstanding any stresses induced during operation of the semiconductor structure 10 without delamination, deformation, or other failure modes.

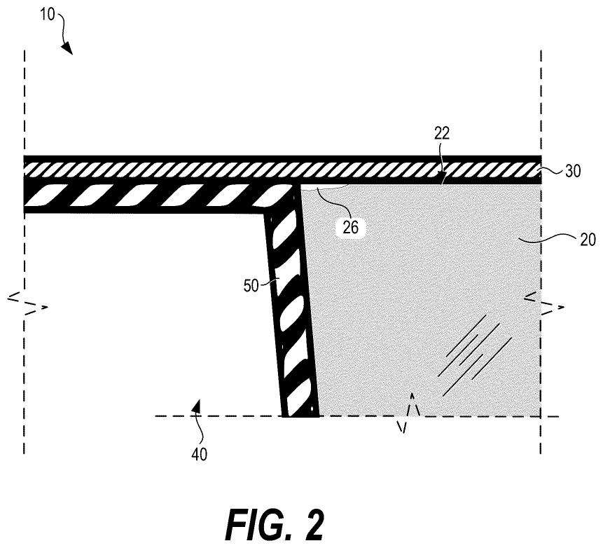

FIG. 2 illustrates the detail area “AA” identified in FIG. 1. A region of delamination 26 (also “region 26”) is depicted in FIG. 2. The region 26 is positioned at a corner of the interface between the metal layers 30 and 50 and proximate to a sidewall of the via 40 in the example shown. The region of delamination 26 is representative of a number of potential issues or defects, such as partial separation of the metal layer 30 from the top surface 22 of the substrate 20, partial separation of the metal layer 30 from metal layer 50, partial separation of the metal layer 50 from the sidewalls of the via opening 40, and possibly other issues. The region 26 may be attributed in part to semiconductor processing limitations. As one example, the region 26 can be caused in part by a lack or failure of adhesion between the metal layer 30 and the top surface 22 of the substrate 20.

The metal layer 30 can be embodied as a stack of metal layers including a titanium (Ti) layer deposited or otherwise formed on the top surface 22 of the substrate 20. The stack of layers in the metal layer 30 can also include a platinum (Pt) layer, a gold (Au) layer, and another Ti layer formed in sequence over the titanium layer on the top surface 22 of the substrate 20. Thus, the metal layer 30 can be embodied as a stack of Ti/Pt/Au/Ti metal layers over the top surface 22 of the substrate 20 in one example, and the metal layer 30 can delaminate or become separated from the top surface 22 in some cases as shown in FIG. 2.

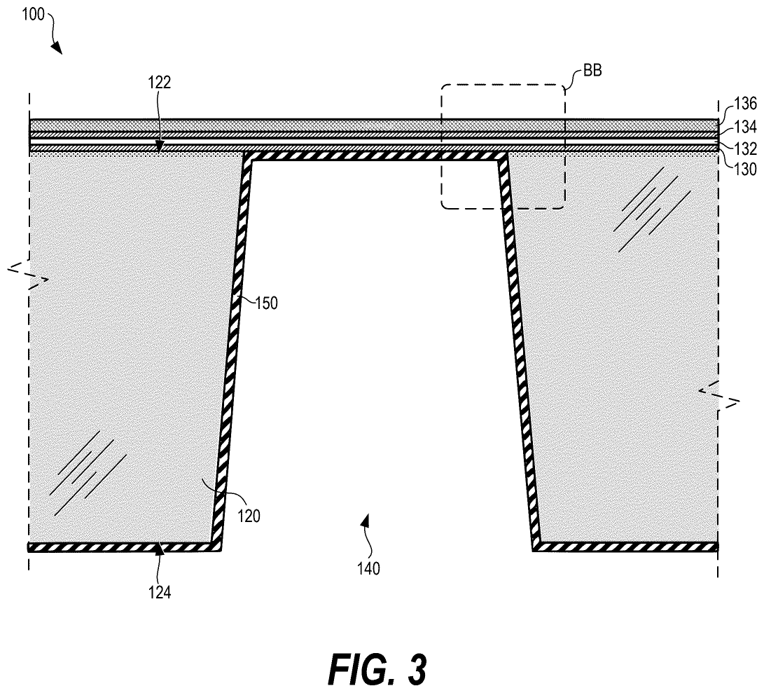

FIG. 3 depicts a partial sectional view of an example semiconductor structure 100 including a landing metal layer having improved adhesion according to various aspects of the embodiments. The semiconductor structure 100 and features of the semiconductor structure 100 are not drawn to any particular size or scale in FIG. 3. The thicknesses of the substrate, layers over the substate, and other features can vary as compared to that shown and as compared to each other. Example thicknesses are described below, although the concepts are not limited to use with substrates or layers having any particular thickness. Additionally, example materials of the substate and the layers over the substate are described below. However, the concepts described herein can be extended to use with other types of materials.

The semiconductor structure 100 includes a substrate 120 having a top surface 122 and a bottom surface 124, a landing metal layer 130 over the substrate 120, a via opening 140 (also “via 140”) that extends through from the bottom surface 124 to the top surface 122 of the substrate 120, and a bottom side metal layer 150 (also “metal layer 150”). The bottom side metal layer 150 extends at least in part over the bottom surface 124 of the substrate 120, over sidewalls of the via 140, and electrically contacts an underside of the landing metal layer 130 in the example shown. Over the landing metal layer 130, the semiconductor structure 100 also includes an insulating layer 132, a metal layer 134 over the insulating layer 132, and an interconnect metal layer 136 over the metal layer 134. Although not illustrated, the semiconductor structure 100 can be part of a larger integrated structure including a number of active and passive devices as would be understood in the field and described below.

The substrate 120 can be embodied as a substrate (e.g., semiconductor wafer) of Gallium Arsenide (GaAs), as one example, although the substrate 120 can be embodied by other semiconducting materials including those described below in other cases. The substrate 120 can also include one or more semiconductor material layers formed in a stack over a GaAs substrate or wafer, such as doped or undoped GaAs layers, doped or undoped Aluminum Gallium Arsenide (AlGaAs) layers, and other semiconductor material layers for conduction layers (e.g., including active regions) of FETs, active cathode and anode layers of PIN, Schottky, or related diodes, and related layers for active devices. The semiconductor material layers over the GaAs substrate 120 can include heterojunctions for active devices as would be understood in the field, although active devices are not illustrated in FIG. 2.

The landing metal layer 130 can be embodied as a stack of metal layers including a first Pt layer deposited or otherwise formed on the top surface 122 of the substrate 120. The first Pt layer that is deposited on the top surface 122 of the substrate 120 can be considered a type of base metal layer in the landing metal layer 130. The stack of layers in the landing metal layer 130 can also include Ti, Pt, Au, and another Ti metal layer formed in sequence over the first Pt layer on the top surface 122 of the substrate 120. Thus, the landing metal layer 130 can be embodied as a stack of Pt/Ti/Pt/Au/Ti metal layers over the top surface 122 of the substrate 120 in one example. The landing metal layer 130 can also consist of a stack of Pt/Ti/Pt/Au/Ti metal layers in some cases, exclusive of any other metal layers or alternative sequence of layers.

The thickness (i.e., as measured the top to the bottom of the page) of each Pt/Ti/Pt/Au/Ti layer in the landing metal layer 130 can range as compared to each other. Example thicknesses include from 10-200 Angstrom (Å) in thickness for the Pt layer, from 100-1000 Å in thickness for the Ti layer, from 500-2000 Å in thickness for the Pt layer, from 1000-10,000 Å in thickness for the Au layer, and from 10-100 Å in thickness for the Ti layer, although other thicknesses can be relied upon. Within those ranges, the Pt/Ti/Pt/Au/Ti layers can be formed to about 100 Å (Pt), 550 Å (Ti), 1000 Å (Pt), 8000 Å (Au), and 50 Å (Ti) in thickness, respectively, in a more particular example, but other thicknesses can be relied upon. The thicknesses of the metal layers can vary based on design needs and other considerations in other cases.

In the semiconductor structure 100 shown in FIG. 3, the landing metal layer 130 is diffused at least in part into the top surface 122 of the substrate 120. More particularly, the Pt in the landing metal layer 130 that is on the top surface 122 of the substrate 120 is diffused at least in part into the top surface of the substrate (i.e., diffused to a depth into the substrate starting from the top surface 122). The Pt in the landing metal layer 130 can be diffused into the substrate 120 by an annealing or related process step as described in further detail below. The diffusion of the Pt from the landing metal layer 130 into the substrate 120 helps to improve adhesion between the landing metal layer 130 and the top surface 122 of the substrate 120. The diffusion and improved adhesion helps to avoid delamination and related defects such as the region 26 illustrated in FIG. 2.

The landing metal layer 130 is not limited to a stack of Pt/Ti/Pt/Au/Ti metal layers in all cases. The landing metal layer 130 can also be embodied as a stack of one or more other metal or metal alloy layers over a first Pt layer, including combinations of one or more Ti, Pt, Au, nickel (Ni), palladium (Pd), zinc (Zn), magnesium (Mg), tantalum (Ta), aluminum (Al), chromium (Cr), or other metal or metal alloy layers, where the first Pt layer is deposited or otherwise formed directly on the top surface 122 of the substrate 120.

It is also not necessary for the landing metal layer 130 to include a base metal layer of Pt directly on the top surface 122 of the substrate 120 in all cases. The landing metal layer 130 can include other base metal layers, and those layers can also be diffused into the top surface 122 of the substrate 120 according to the concepts described herein. As examples, the base metal layer of the landing metal layer 130 can be a Pd, Zn, Mg, Ti, Ni, Ta, Al, Cr, or other suitable base metal layer. The base metal layer can be selected for suitable diffusion into the substrate 120 based on the composition of the substrate 120, the processing tools available, and related factors.

The insulating layer 132 can be embodied as a layer of Silicon Nitride (e.g., Si₃N₄) or a related dielectric insulating material. The insulating layer 132 acts as an insulation layer of a metal-insulator-metal (MIM) capacitor in the semiconductor structure 100. The insulating layer 132 is positioned between the landing metal layer 130 and the metal layer 134. Together, the landing metal layer 130, insulating layer 132, and metal layer 134 can form a MIM capacitor in the semiconductor structure 100. Although not illustrated in FIG. 3, the semiconductor structure 100 and MIM capacitor can be part of a larger integrated structure including a number of active and passive devices as would be understood in the field.

The metal layer 134 can be embodied as a stack of metal layers. In one example, the stack of metal layers includes a Ti layer, a Pt layer, an Au layer, and another Ti layer formed in sequence over the insulating layer 132. Thus, the metal layer 134 can be embodied as a stack of Ti/Pt/Au/Ti metal layers over the insulating layer 132. The metal layer 134 can also consist of a stack of Ti/Pt/Au/Ti metal layers in some cases, exclusive of any other metal layers or alternative sequence of layers. The metal layer 134 is thus different in composition as compared to the landing metal layer 130, because the metal layer 134 includes Ti/Pt/Au/Ti metal layers and the landing metal layer 130 includes Pt/Ti/Pt/Au/Ti metal layers. No intentional attempt is made to diffuse the metal layer 134 in the semiconductor structure 100, and no particular annealing steps are performed for that purpose. The metal layer 134 is not limited to a stack of Ti/Pt/Au/Ti metal layers, and the metal layer 134 can also be embodied as a stack of one or more other metal or metal alloy layers in other examples, including combinations of one or more Ti, Pt, Au, Ni, Pd, Zn, Mg, Ti, Ta, Al, Cr, and other metal or metal alloy layers.

The thickness of each Ti/Pt/Au/Ti layer in the metal layer 134 can range as compared to each other. Example thicknesses include from 100-1000 Å in thickness for the Ti layer, from 500-2000 Å in thickness for the Pt layer, from 1000-8,000 Å in thickness for the Au layer, and from 10-100 Å in thickness for the Ti layer, although other thicknesses can be relied upon. Within those ranges, the Ti/Pt/Au/Ti layers can be formed to about 550 Å (Ti), 1000 Å (Pt), 5000 Å (Au), and 50 Å (Ti) in thickness, respectively, in a more particular example, but other thicknesses can be relied upon. The thicknesses of the metal layers can vary based on design needs and other considerations in other cases.

The interconnect metal layer 136 can be embodied as a metal layer or a stack of one or more metal layers. The interconnect metal layer 136 can be formed as an air bridge interconnection layer in some cases, and the interconnect metal layer 136 can be relied upon to electrically couple the metal layer 134 to a metal contact region of an active device, for example.

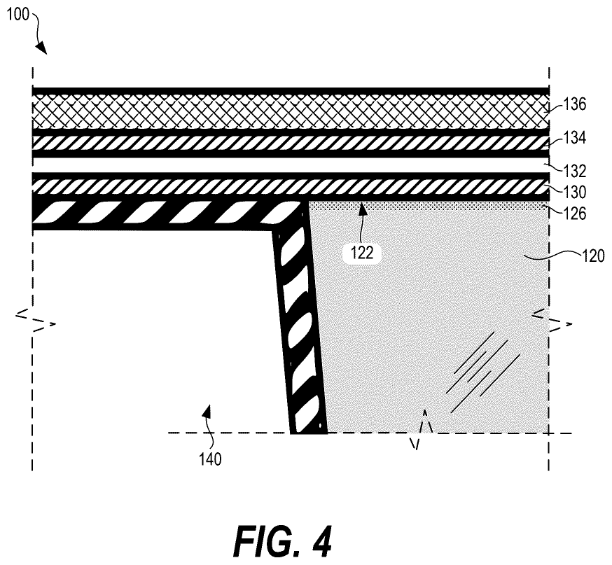

FIG. 4 illustrates the detail area “BB” identified in FIG. 3 according to various aspects of the embodiments. FIG. 4 depicts a region of diffusion 126 in the substrate 120, where Pt from the landing metal layer 130 has diffused in part into the top surface 122 of the substrate 120. The Pt in the landing metal layer 130 can be diffused into the substrate 120 by an annealing or related process step as described in further detail below. The diffusion of the Pt from the landing metal layer 130 into the substrate 120 helps to improve adhesion between the landing metal layer 130 and the top surface 122 of the substrate 120. The diffusion and improved adhesion helps to avoid delamination and related defects such as the region 26 illustrated in FIG. 2.

Together, the landing metal layer 130, insulating layer 132, and metal layer 134 form a MIM capacitor in the semiconductor structure 100. The semiconductor structure 100 and MIM capacitor can be part of a larger integrated structure including a number of active and passive devices as would be understood in the field. A MIM capacitor is just one example of a passive circuit component that can be realized in part using the landing metal layer 130 and the concepts of landing metal layer adhesion alloying described herein. In other examples and embodiments, the landing metal layer 130 can be relied upon to form other circuit components, such as inductors, transmission lines, RF couplers, device interconnects, bond pads, and other components and features. Thus, the insulating layer 132, metal layer 134, and interconnect metal layer 136 can all be omitted in some cases, such as if the landing metal layer 130 is relied upon to form an inductor, transmission line, device interconnect, bond pad, or other component.

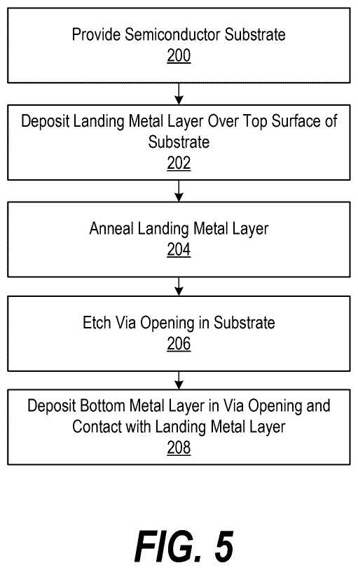

FIG. 5 illustrates an example process for forming a semiconductor structure with a landing metal layer having improved adhesion according to various aspects of the embodiments. The process steps shown in FIG. 5 are representative of only a subset of those that can be performed in a larger semiconductor manufacturing process for a semiconductor structure, MMIC, or related integrated semiconductor device. Such a process can be relied upon to form a MMIC or related integrated semiconductor device with one or more diodes, transistors, capacitors, inductors, transmission lines, RF couplers, device interconnects, and other components.

The steps shown in FIG. 5 can be performed in combination with additional processing steps as would be understood in the field. The additional steps can occur before, after, and intervene among one or more of the steps shown in FIG. 5. As examples, before the steps shown in FIG. 5, one or more steps for forming active devices can be performed, such as steps of depositing ohmic metal layers for source and drain contacts of transistors, depositing metal layers for anode or cathode contacts of diodes, injecting ions for device isolation and the reduction of leakage currents, and other steps. Injecting ions can include implanting Boron ions to damage the crystal lattice of active layers, and other ions can be injected for crystal lattice damage and device isolation. The steps shown in FIG. 5 are also illustrated in a particular order, although the sequence of the steps can be rearranged or occur in other sequences. The process steps shown in FIG. 5 can be relied upon to form a range of different passive and active circuit components or features thereof.

Step 200 includes providing a semiconductor substrate. The substrate can be a GaAs substrate, for example, such as the substrate 120 described above. The substrate 120 can be embodied as a GaAs substrate, although the substrate 120 can be embodied by other semiconducting materials. The substrate 120 can also include one or more semiconductor material layers formed in a stack over a GaAs substrate or wafer, such as doped or undoped GaAs layers, doped or undoped AlGaAs layers, and other semiconductor material layers for conduction layers (e.g., including active regions) of FETs, active cathode and anode layers of PIN, Schottky, or related diodes, and related layers for active devices. The semiconductor material layers over the GaAs substrate 120 can include heterojunctions for active devices as would be understood in the field. The thickness of the substrate 120 can range depending upon the purpose or application of the semiconductor structure being manufactured.

The substrate 120 can be sourced or formed in any suitable way. As one example, the substrate 120 can be sourced from a vendor as a GaAs substrate including a stack of semiconductor material layers over the GaAs substrate (e.g., an epiwafer). Alternatively, a GaAs substate can be sourced separately, and a stack of semiconductor material layers can be epitaxially grown, deposited, or otherwise formed over the GaAs substrate. The layers can be formed using Metalorganic Chemical Vapour Deposition (MOCVD), although other epitaxial or deposition process steps can be used to form the layers over the GaAs substrate.

Step 202 includes depositing a landing metal layer over a top surface of the substrate provided at step 200. Referring to FIG. 3 as an example, step 202 can include depositing the landing metal layer 130 over the top surface 122 of the substrate 120. To define the size and shape of the landing metal layer 130, step 202 can include applying a photoresist layer over the top surface 122 of the substrate 120, patterning the photoresist layer, and selectively removing the photoresist layer over a defined region of the top surface 122. The defined region can be an exposed region of the top surface 122 of the substrate 120 on which the landing metal layer 130 will be deposited. Step 202 also includes depositing one or more layers of metal on the top surface 122 of the substrate 120 in the defined region, to form the landing metal layer 130 on the top surface 122 of the substrate 120. The process can also include lifting off or removing metal deposited outside of the defined region, by stripping the remaining photoresist and metal outside of the defined region (e.g., lift-off) or other techniques.

The landing metal layer 130 can be deposited starting with a first or base Pt metal layer on the top surface 122 of the substrate 120 in step 202. Subsequent Ti, Pt, Au, and Ti metal layers can be deposited over the first or base Pt layer in one example to form the landing metal layer 130. The stack of Pt/Ti/Pt/Au/Ti metal layers in the landing metal layer 130 can be deposited in any suitable way, such as by evaporation, sputtering, and other physical vapor deposition techniques, chemical vapor deposition techniques, plating techniques, or other techniques. Each Pt/Ti/Pt/Au/Ti layer in the landing metal layer 130 can be deposited or otherwise formed to any suitable thickness including those discussed above. In other cases, one or more Ti, Pt, Au, Ni, Pd, Zn, Mg, Ta, Al, Cr, or other metal or metal alloy layers can be deposited over the first or base Pt layer as part of step 202. The thicknesses of the metal layers can vary based on design needs and other considerations in other cases.

The landing metal layer 130 can be deposited with a different first or base metal layer (i.e., other than Pt) in some cases at step 202. For example, step 202 can include depositing a base metal layer of Pd, Zn, Mg, Ti, Ni, Ta, Al, Cr, or another suitable base metal layer on the top surface 122 of the substrate 120. The base metal layer can be selected at step 202 for suitable diffusion into the substrate 120 based on the composition of the substrate 120, the processing tools available, and related factors. One or more subsequent Ti, Pt, Au, Ni, Pd, Zn, Mg, or other metal or metal alloy layers can also be deposited over the first or base layer as part of step 202.

Step 204 includes annealing the landing metal layer that was deposited at step 202. More particularly, step 204 includes annealing the landing metal layer deposited at step 202 to diffuse it at least in part into the top surface of the substrate provided at step 200. The landing metal layer 130 and substrate 120 shown in FIG. 3 can be annealed in any suitable way, such as by furnace annealing, hot plate alloying, heating in an oven or chamber, or using other known techniques. Step 204 thus includes alloying and diffusing in part the landing metal layer 130 into the top surface 122 of the substrate 120 and can result in the region of diffusion 126 shown in FIG. 4. The annealing at step 204 can be performed at a suitable temperature or temperatures, each for a sufficient amount of time, to diffuse the landing metal layer 130 into the top surface 122 of the substrate 120 for improved adhesion between them. More particularly, the annealing at step 204 can be performed to diffuse the first or base metal layer of the landing metal layer 130, at least in part, into the top surface 122 of the substrate 120 for improved adhesion.

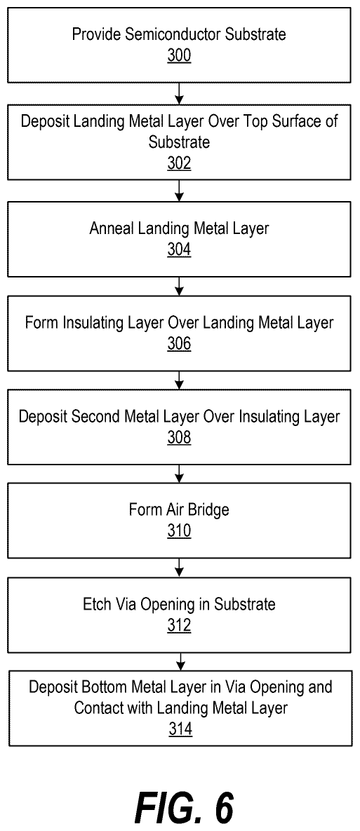

Additional process steps can be performed after step 204 and before step 206 in some cases. As examples, steps for forming insulating layers, depositing additional metal layers, air bridges, gate contacts for transistors, passivating and encapsulating devices and circuit structures, and other steps can be performed before step 206. Encapsulating can include applying a layer of Benzocyclobutene (BCB) or related encapsulant. The encapsulant can be formed or applied by spin coating or any other suitable application techniques. The encapsulant can provide scratch protection and underfills for metal air bridges, as one example. Additional examples are described below with reference to FIG. 6. Steps 206 and 208 are examples of backside processing steps. The bottom surface 124 of the substrate 120 can be thinned by mechanical grinding, wet chemical etching polishing, or other thinning processes, for example, before steps 206 and 208, and other steps can also be performed after steps 206 and 208.

Step 206 includes etching a via opening through from a bottom surface to a top surface of the substrate, under the landing metal layer. For example, step 206 can include etching or otherwise forming the via opening 140 in the substrate 120 so that it extends through from the bottom surface 124 to the top surface 122 of the substrate 120. The via 140 can be formed by any suitable etching techniques, such as reactive ion etching, wet etching, dry etching and plasma etching.

Step 208 includes depositing a bottom side metal layer over the bottom surface of the substrate, over sidewalls of the via, and that electrically contacts an underside of the landing metal layer. Referring to FIG. 3, step 208 can include depositing the bottom side metal layer 150 over the bottom surface 124 of the substrate 120, over the sidewalls of the via 140, and in electrical contact with an underside of the landing metal layer 130. The bottom side metal layer 150 can act as a ground layer in some cases, providing an electrical connection to ground for the landing metal layer 130. The bottom side metal layer 150 can also act as an electrical connection to ground for a cathode or anode contact of a diode, for an ohmic contact of a transistor, or for connection to another active circuit component. In one example, the bottom side metal layer 150 can be formed by sputtering one or more seed layers of metal, such as Au, followed by evaporating Ti, Pt, and Au layers. Other approaches and metal layers or metal alloys can be relied upon for the bottom side metal layer 150. Additional process steps can be performed after step 208 as needed.

The process shown in FIG. 5 can avoid defects such as the region of delamination 26 shown in FIG. 2 and described above. The process can also ensure good adhesion between the landing metal layer deposited at step 202 and the substrate provided at step 200. Additionally, the process can also ensure robust electrical contact between the landing metal layer deposited at step 202 and the bottom metal layer deposited at step 208 over time and even over significant process manufacturing and operating temperature ranges and temperature cycling.

FIG. 6 illustrates another example process for forming a semiconductor structure with a landing metal layer having improved adhesion according to various aspects of the embodiments. The process steps shown in FIG. 6 are representative of only a subset of those that can be performed in a larger semiconductor manufacturing process for a semiconductor structure, MMIC, or related integrated semiconductor device. Such a process can be relied upon to form a MMIC or related integrated semiconductor device with one or more diodes, transistors, capacitors, inductors, transmission lines, RF couplers, device interconnects, and other components.

The steps shown in FIG. 6 can be performed in combination with additional processing steps as would be understood in the field. The additional steps can occur before, after, and intervene among one or more of the steps shown in FIG. 6. As examples, before the steps shown in FIG. 6, one or more steps for forming active devices can be performed, such as steps of depositing ohmic metal layers for source and drain contacts of transistors, depositing metal layers for anode or cathode contacts of diodes, injecting ions for device isolation and the reduction of leakage currents, and other steps. The steps shown in FIG. 6 are also illustrated in a particular order, although the sequence of the steps can be rearranged or occur in other sequences. The steps are also described in connection with FIGS. 3 and 4 and MIM capacitors for example context, but the process steps shown in FIG. 6 can be relied upon to form other passive and active circuit components or features thereof.

Step 300 includes providing a semiconductor substrate, step 302 includes depositing a landing metal layer over a top surface of the substrate, and step 304 includes annealing the landing metal layer. Steps 300, 302, and 304 can be similar to or the same as steps 200, 202, and 204 in FIG. 5. Additional process steps are performed after step 304.

Step 306 includes forming an insulating layer over the landing metal layer. For example, referring to FIG. 3, step 306 can include forming the insulating layer 132 as a layer Si₃N₄ or a related dielectric insulating material over the landing metal layer 130. The insulating layer 132 can act as an insulation layer of MIM capacitor in the semiconductor structure 100 as described below.

Step 308 includes depositing a second metal layer over the insulating layer. For example, step 308 can include depositing the metal layer 134 over the insulating layer 132 shown in FIG. 3. The metal layer 134 can deposited as a stack of metal layers. In one example, the stack of metal layers includes a Ti layer, a Pt layer, an Au layer, and another Ti layer formed in sequence over the insulating layer 132. Thus, the metal layer 134 can be embodied as a stack of Ti/Pt/Au/Ti metal layers over the insulating layer 132. The metal layer 134 can also consist of a stack of Ti/Pt/Au/Ti metal layers in some cases, exclusive of any other metal layers or alternative sequence of layers. The metal layer 134 is thus different in composition as compared to the landing metal layer 130, because the metal layer 134 includes Ti/Pt/Au/Ti metal layers and the landing metal layer 130 includes Pt/Ti/Pt/Au/Ti metal layers. No intentional attempt is made to diffuse the metal layer 134 in the semiconductor structure 100, and no particular annealing steps are performed for that purpose in FIG. 6. The metal layer 134 is not limited to a stack of Ti/Pt/Au/Ti metal layers, and the metal layer 134 can also be embodied as a stack of one or more other metal or metal alloy layers in other examples, including combinations of one or more Ti, Pt, Au, Ni, Pd, Zn, Mg, Ti, Ta, Al, Cr, and other metal or metal alloy layers.

The insulating layer 132 is positioned between the landing metal layer 130 and the metal layer 134. Together, the landing metal layer 130, insulating layer 132, and metal layer 134 can form a MIM capacitor in the semiconductor structure 100 formed by the process shown in FIG. 6. The semiconductor structure 100 and MIM capacitor can be part of a larger integrated structure including a number of active and passive devices as would be understood in the field.

Step 310 includes forming an air bridge or other interconnect. For example, step 310 can include forming the interconnect metal layer 136 shown in FIG. 3, which can be formed as an air bridge interconnection layer. The interconnect metal layer 136 can be relied upon to electrically couple the metal layer 134 to a metal contact region of an active device, for example.

Additional process steps can be performed after step 310 and before step 312 in some cases. As examples, steps for passivating and encapsulating devices and circuit structures and other steps can be performed before step 312. Steps 312 and 314 are examples of backside processing steps. The bottom surface 124 of the substrate 120 can be thinned by mechanical grinding, wet chemical etching polishing, or other thinning processes, for example, before steps 312 and 314, and other steps can also be performed after steps 312 and 314.

Step 312 includes etching a via opening through from a bottom surface to a top surface of the substrate, under the landing metal layer. For example, step 312 can include etching or otherwise forming the via opening 140 in the substrate 120 so that it extends through from the bottom surface 124 to the top surface 122 of the substrate 120. The via 140 can be formed by any suitable etching techniques, such as reactive ion etching, wet etching, dry etching and plasma etching.

Step 314 includes depositing a bottom side metal layer over the bottom surface of the substrate, over sidewalls of the via, and that electrically contacts an underside of the landing metal layer. Referring to FIG. 3, step 314 can include depositing the bottom side metal layer 150 over the bottom surface 124 of the substrate 120, over the sidewalls of the via 140, and in electrical contact with an underside of the landing metal layer 130. The bottom side metal layer 150 can act as a ground layer in some cases, providing an electrical connection to ground for the landing metal layer 130, which acts as a capacitor plate of the MIM capacitor. The bottom side metal layer 150 can be formed by sputtering one or more seed layers of metal, such as Au, followed by evaporating Ti, Pt, and Au layers. Other approaches and metal layers or metal alloys can be relied upon for the bottom side metal layer 150. Additional process steps can be performed after step 314 as needed.

The process shown in FIG. 6 can avoid defects such as the region of delamination 26 shown in FIG. 2 and described above in MIM capacitors. The process can also ensure good adhesion between the landing metal layer deposited at step 202 and the substrate provided at step 200. Additionally, the process can also ensure robust MIM capacitors and over time and even over significant process manufacturing and operating temperature ranges and temperature cycling.

The process flow diagrams in FIGS. 5 and 6 are provided as examples for forming semiconductor structures, integrated semiconductor devices, MMIC devices, and other integrated devices including a range of active and passive devices with improved landing metal layer adhesion and alloying. The processes can be relied upon to manufacture a variety of electrical circuits interconnected in a monolithic format with lower defects. Variations on the process flows and steps are within the scope of the embodiments. Additionally, although FIGS. 3-6 depict a single landing metal layer and via under the landing metal layer, the concepts are not limited to semiconductor structures with only a single landing metal layer and via with bottom side metal layer electrically coupled to the back side of the landing metal layer through the via. The semiconductor structures can include any number of electrically separated (or electrically coupled) landing metal layers, vias, and bottom side metal layers.

The embodiments and concepts described herein are useful for manufacturing devices in, on, and over GaAs, silicon (e.g., GaN-on-Si), silicon carbide (e.g., GaN-on-silicon carbide (SiC)), as well as other types of substrate materials. As used herein, the phrase “gallium nitride material(s)” or “GaN material(s)” refers to gallium nitride and any of its alloys, such as aluminum gallium nitride (Alₓ Ga₍₁₋ₓ₎ N), indium gallium nitride (In_{y} Ga_{(1-y)} N), aluminum indium gallium nitride (Alₓ In_{y} Ga_{(1-x-y)} N), gallium arsenide phosphide nitride (GaAsa Pb N (1-a-b)), aluminum indium gallium arsenide phosphide nitride (Alₓ In_{y} Ga_{(1-x-y)} ASₐ P_{b} N_{(1-a-b)}), among others. The gallium nitride materials can be formed over a silicon, silicon carbide, or other type of substrate. The term “gallium nitride” or GaN semiconductor refers directly to gallium nitride, exclusive of its alloys.

The structures and methods described herein can be used to fabricate a wide variety of useful integrated circuits. For example, the electrodes described above can be integrated with various components in a monolithic circuit format suitable for microwave circuit applications. Although embodiments have been described herein in detail, the descriptions, including the dimensions states, are by way of example.

The features, structures, or characteristics described herein may be combined in one or more embodiments in any suitable manner, and the features discussed in the embodiments can be interchangeable in many applications. In the foregoing description, certain details are provided to convey the concepts and embodiments of the present disclosure. However, a person skilled in the art will appreciate that the technical concepts and solutions of the disclosure can be practiced without all of the specific details in every instance, or other methods, components, materials, and the like may be employed. To some extent and in some cases, well-known structures, materials, or process steps are not shown or described in detail to avoid obscuring other aspects of the concepts.

Although relative terms of orientation, such as “above,” “below,” “upper,” “lower,” “under,” and “over,” may be used to describe the structural orientation of certain elements, the terms are used to clarify the relative positions and orientations of the elements in the examples shown in the drawings. It should be understood that if the device is turned upside down, the “upper” component will become a “lower” component, and so on.

As described herein, a reference to the “thickness” of a substrate or material layer is a measurement of the cross-sectional thickness of the substrate or layer from the top surface of the substrate or layer to the bottom surface of the substrate or layer. Additionally, a “top” or “top surface” of a layer is positioned toward the top of the page, and a “bottom” or “bottom surface” of a layer is positioned toward the bottom of the page, unless otherwise specified.

As used herein, terms such as “a,” “an,” “the,” and “said” are used to indicate the presence of one or more elements and components. The terms “comprise,” “comprising,” “include,” “including,” “have,” “having,” “contain,” “containing,” and their variants are open ended and can include additional elements, components, etc., in addition to the listed elements, components, etc. unless otherwise specified. The terms “first,” “second,” etc. are used only as labels, rather than a limitation for a number of the objects.

The features of the embodiments described herein are representative and, in alternative embodiments, certain features and elements can be added, omitted, and interchanged with each other. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, at least the following is claimed:

1. A semiconductor structure comprising:
a substrate comprising a top surface and a bottom surface;
a landing metal layer on and diffused at least in part into the top surface of the substrate;
a via that extends through from the bottom surface to the top surface of the substrate; and
a bottom side metal layer over the bottom surface of the substrate, over sidewalls of the via, and that electrically contacts an underside of the landing metal layer.

2. The semiconductor structure according to claim 1, wherein:
the landing metal layer comprises a stack of metal layers; and
the stack of metal layers comprises a base metal layer of one of platinum, palladium, zinc, magnesium, titanium, nickel, tantalum, aluminum, or chromium on and diffused at least in part into the top surface of the substrate.

3. The semiconductor structure according to claim 1, wherein:
the landing metal layer comprises a stack of metal layers; and
the stack of metal layers comprises a platinum layer on and diffused at least in part into the top surface of the substrate, a titanium layer, a second platinum layer, a gold layer, and a second titanium layer.

4. The semiconductor structure according to claim 1, further comprising:
an insulating layer over the landing metal layer; and
a second metal layer over the insulating layer.

5. The semiconductor structure according to claim 4, wherein the landing metal layer, the insulating layer, and the second metal layer comprise a metal-insulator-metal (MIM) capacitor.

6. The semiconductor structure according to claim 4, wherein:
the landing metal layer comprises a base metal layer of one of platinum, palladium, zinc, or magnesium on and diffused at least in part into the top surface of the substrate; and
the second metal layer comprises a titanium layer on the insulating layer.

7. The semiconductor structure according to claim 4, wherein the second metal layer is electrically coupled to a contact of an active semiconductor device by an interconnect metal layer.

8. The semiconductor structure according to claim 4, wherein the second metal layer is electrically coupled to a contact of an active semiconductor device by a metal air bridge.

9. The semiconductor structure according to claim 1, wherein the landing metal layer comprises a metal layer for a capacitor, an inductor, or a bond pad.

10. A semiconductor structure comprising:
a landing metal layer on and diffused at least in part into a top surface of a substrate;
a via that extends through from a bottom surface to the top surface of the substrate under the landing metal layer; and
a bottom side metal layer in the via and that electrically contacts an underside of the landing metal layer.

11. The semiconductor structure according to claim 10, wherein the landing metal layer comprises a base meal layer of one of platinum, palladium, zinc, magnesium, titanium, nickel, tantalum, aluminum, or chromium on and diffused at least in part into a top surface of a substrate.

12. The semiconductor structure according to claim 10, further comprising:
an insulating layer over the landing metal layer; and
a second metal layer over the insulating layer.

13. The semiconductor structure according to claim 12, wherein the landing metal layer, the insulating layer, and the second metal layer comprise a metal-insulator-metal (MIM) capacitor.

14. The semiconductor structure according to claim 12, wherein:
the landing metal layer consists of a stack of aplatinum layer on and diffused at least in part into a top surface of a substrate, a titanium layer over the platinum layer, a second platinum layer over the titanium layer, a gold layer over the second platinum layer, and a second titanium layer over the gold layer; and
the second metal layer comprises a titanium layer on the insulating layer.

15. The semiconductor structure according to claim 12, wherein the second metal layer is electrically coupled to a contact of an active semiconductor device by an interconnect metal layer.

16. The semiconductor structure according to claim 12, wherein the second metal layer is electrically coupled to a contact of an active semiconductor device by a metal air bridge.

17. A process for manufacturing a landing metal layer, comprising:
providing a substrate comprising a top surface and a bottom surface;
depositing a landing metal layer over the top surface of the substrate;
annealing the landing metal layer to diffuse the landing metal layer at least in part into the top surface of the substrate;
etching a via opening through from the bottom surface to the top surface of the substrate; and
depositing a bottom side metal layer over the bottom surface of the substrate, over sidewalls of the via, and that electrically contacts an underside of the landing metal layer.

18. The process according to claim 17, further comprising:
before the etching and after the annealing, forming an insulating layer over the landing metal layer; and
depositing a second metal layer over the insulating layer.

19. The process according to claim 18, wherein the landing metal layer, the insulating layer, and the second metal layer comprise a metal-insulator-metal (MIM) capacitor.

20. The process according to claim 18, wherein the landing metal layer comprises a base metal layer of one of platinum, palladium, zinc, magnesium, titanium, nickel, tantalum, aluminum, or chromium on and diffused at least in part into the top surface of the substrate.
